(19) United States
(12) Patent Application Publication
(10) Pub. No.: US 2022/0205087 A1
(43) Pub. Date: Jun. 30, 2022

(54) IN-CAVITY CLEANING METHOD

(71) Applicant: PIOTECH INC., Shenyang (CN)

(72) Inventors: Yaxin Zhang, Shenyang (CN); Peipei Li, Shenyang (CN)

(21) Appl. No.: 17/550,190

(22) Filed: Dec. 14, 2021

(30) Foreign Application Priority Data
Dec. 31, 2020 (CN) 202011626986.5

(51) Int. Cl. C23C 16/44; C23C 16/52; H01J 37/32

(52) U.S. Cl. CPC C23C 16/4405; H01J 37/32862; C23C 16/52

(57) ABSTRACT

An in-cavity cleaning method includes: a lower electrode temperature control step of controlling a lower electrode to a predetermined temperature; an electrode distance adjustment step of elevating the lower electrode and controlling a distance between an upper electrode and the lower electrode; a film deposition step of depositing a film on a substrate; a cleaning gas introducing step of introducing a cleaning gas in a plasma state from the upper electrode; and a cleaning gas pressure control step of adjusting a pressure of the cleaning gas in a cavity by adjusting an opening of a valve.

### CROSS-REFERENCE TO RELATED APPLICATIONS

This non-provisional application claims priority under 35 U.S.C. § 119(a) to Patent Application No(s). 202011626986.5 filed in China on Dec. 31, 2020, the entire contents of which are hereby incorporated by reference.

### BACKGROUND OF THE INVENTION

### Field of the Invention

The present invention relates to an in-cavity cleaning method and, more particularly, to an in-cavity cleaning method applied to semiconductor film manufacturing.

### Description of the Prior Art

Plasma chemical vapor deposition is primarily used for forming a film on a substrate, but at the same time also forms a film on surfaces of components in a cavity. The film on surfaces of these components in the cavity falls off over an extended period of time, and forms particles falling on a surface of the substrate and therefore affects the performance of the deposited film on the surface of the substrate. Thus, once the substrate has fully undergone deposition and leaves the cavity, it is needed to use a cleaning gas to clean an environment and surfaces of the components in the cavity.

The duration of cleaning directly affects the production capacity of semiconductor equipment, and therefore, there is a need for enhancing cleaning efficiency for an environment and surfaces of components in a cavity.

### SUMMARY OF THE INVENTION

It is an object of the present invention to solve the issues above, so as to enhance the efficiency of cleaning any excess film in a cavity formed by the plasma chemical vapor deposition, and increase the production capacity of semiconductor equipment.

An in-cavity cleaning method includes: a lower electrode temperature control step of controlling a lower electrode to a predetermined temperature; an electrode distance adjustment step of elevating the lower electrode and controlling a distance between an upper electrode and the lower electrode; a film deposition step of depositing a film on a substrate; a cleaning gas introducing step of introducing a cleaning gas in a plasma state from the upper electrode of a cavity into the cavity; and a cleaning gas pressure control step of adjusting a pressure of the cleaning gas to switch between a first pressure and a second pressure by a valve adjustment means, wherein the first pressure is greater than the second pressure.

Preferably, the predetermined temperature is 150° C. to 400° C. Preferably, the method further includes driving the elevation of the lower electrode by a motor, and controlling the distance between the upper electrode and the lower electrode to be 6 to 15 mm. Preferably, the cleaning gas is NF₃, and after fluorine ions are formed therefrom by a plasma source generator, the fluorine ions are introduced into the cavity from the upper electrode. Preferably, the flow rate of the cleaning gas introduced into the cavity is 1500 to 4500 sccm. Preferably, the valve adjustment means controls the pressure of the cleaning gas in the cavity by a butterfly valve. Preferably, the pressure in the cavity switches between the first pressure and the second pressure in the cleaning process, wherein the first pressure is 3 to 6 torr and the second pressure is 0.5 to 2 torr. Preferably, the first pressure is a high-pressure state and the second pressure is a low-pressure state, and a switching frequency between the two is once per 5 to 15 seconds.

By quickly switching the pressure of the cleaning gas, the present invention enhances the efficiency of cleaning any excess film in a cavity formed by plasma chemical vapor deposition, and increases the production capacity of semiconductor equipment.

### BRIEF DESCRIPTION OF THE DRAWINGS

Detailed description of the present invention are given in the embodiments with the accompany drawings below, in which:

FIG. 1 is a configuration diagram of a cavity of a plasma chemical vapor deposition device according to a first embodiment of the present invention; and

FIG. 2 is a cross-sectional schematic diagram of a second side cavity according to the first embodiment of the present invention,

wherein 11 epresents a first side cavity, 12 represents a second side cavity, 111 represents an upper electrode, 112 represents a lower electrode, and a to i represent positions.

### DETAILED DESCRIPTION OF THE EMBODIMENTS

### First Embodiment

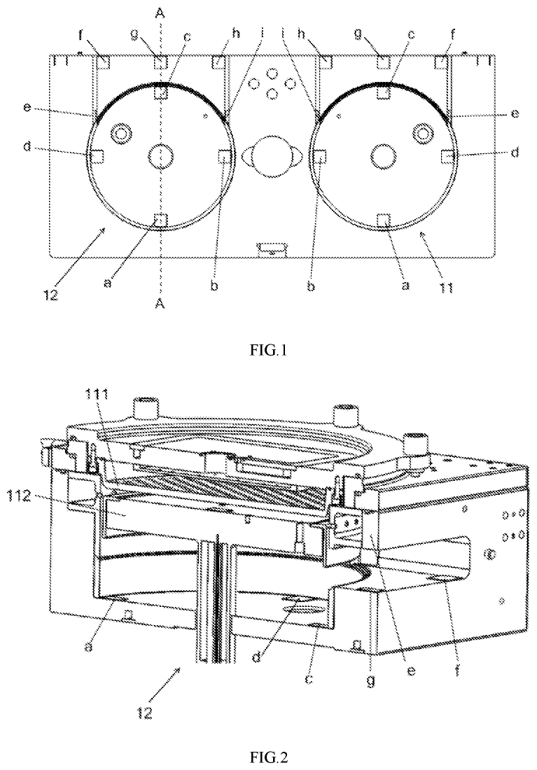

FIG. 1 shows a configuration diagram of a processing cavity of a plasma chemical vapor deposition device according to a first embodiment of the present invention, and is a top view showing the bottom and configuration (for example, no heating plate is installed) of the cavity. As shown, the deposition device includes a first side cavity (the right of the drawing), and a second side cavity (the left of the drawing). The first side cavity and the second side cavity are identical and symmetrically arranged. At nine positions a to i on the first side cavity and the second side cavity, sampling blocks for measuring film thicknesses are placed. The sampling blocks may be components taken out of the cavity, and the film thicknesses formed by deposition may be measured by a known means, so as to estimate conditions of films accumulated on other components in the cavity. FIG. 2 shows a cross-sectional schematic diagram of the second side cavity taken along section line A-A in FIG. 1.

FIG. 2 shows a schematic diagram of a second side cavity according to the first embodiment of the present invention. As shown, the second side cavity fundamentally includes therein an upper electrode 111 serving as a showerhead element located on the top of the cavity, a lower electrode 112 serving as a heating plate and a thermocouple (not shown). The heating plate includes a heating unit, and is connected to a temperature control device (not shown). Moreover, elevation of the heating plate is controlled by a motor (not shown). One or more position sensors may be provided and configured to determine a distance between the upper electrode 111 and the lower electrode 112. The upper electrode 111 is at a fixed position, and includes multiple through holes for a cleaning gas to flow into the cavity. The lower electrode 112 (that is, the heating plate) is for heating a substrate. The thermocouple may be arranged on a wall of the cavity or on the heating plate to measure the temperature in the cavity. The motor is for controlling the position of the lower electrode, and is used in conjunction with the position sensor(s) to control the distance between the upper electrode 111 and the lower electrode 112.

The cleaning gas used in this embodiment is NF₃. Specific steps of an in-cavity cleaning method of the present invention are described below.

(1) The temperature of the heating plate, that is, the lower electrode 112, is controlled to be 400° C., the temperature is measured in real time by the thermocouple, and the temperature is controlled by the temperature control device at a temperature control precision range of ±0.75%; that is, in this embodiment, the temperature ranges between 397° C. and 403° C.

(2) From the cavity, a substrate of which a surface having a film formed thereon by plasma chemical vapor deposition is taken out by a mechanical arm, and at the same time, the film thicknesses of the sampling blocks placed at the nine different positions a to i shown in FIG. 2 are measured. As shown by the table below, it is assumed that films have been deposited at all of the nine different positions a to i in the first side cavity 11 and the second side cavity 12, such that residual films are formed.

Thicknesses (Å) of residual films after deposition
by plasma chemical vapor deposition

| Position | First side cavity | Second side cavity |
|---|---|---|
| a | 136 | 82 |
| b | 75 | 129 |
| c | 68 | 122 |
| d | 122 | 75 |
| e | 204 | 197 |
| f | 143 | 231 |
| g | 116 | 102 |
| h | 136 | 238 |
| i | 102 | 197 |

(3) The distance between the upper electrode and the lower electrode is adjusted and controlled to be 8 to 10 mm by the motor and the position sensor(s).

(4) The 3000 to 3500 sccm NF₃ is introduced as a cleaning gas. The cleaning gas first forms partial fluorine ions by a plasma source generator placed at a remote end, and enters in the form of partial fluorine ions the first side cavity and the second side cavity from the upper electrode 111.

(5) The pressures in the first side cavity and the second side cavity are controlled by a known means (for example, adjusting an opening of a butterfly valve). The pressures of the first side cavity and the second side cavity are synchronously switched between a high-pressure state and a low-pressure state, wherein the high-pressure state is 3 to 6 torr and the low-pressure state is 0.5 to 2 torr.

(6) With the adjustment of the butterfly valve, the cleaning gas is allowed to work at the high-pressure state for 10 s and then switched to the low-pressure state for 10 s, and such switching round is repeated four times (where the time needed for switching is approximately 0.1 s).

With the processing method of the present invention, as shown in the table below, the cleaning efficiency per unit time in the cavity can be increased by about 40% compared to conventional processing (wherein the conventional processing is working at a high-pressure state for 40 s and at a low-pressure state for 40 s for one round).

| | Thickness (Å) of film removed | | Thickness (Å) of film | | Increased |
|---|---|---|---|---|---|
| | by the conventional processing | | removed by the processing of | | percentage in |
| | 80 s | | the present invention 80 s | | cleaning |
| Position | First side | Second side | First side | Second side | efficiency |
| a | 1646 | 1754 | 2106 | 2437 | 33.6% |
| b | 1324 | 1703 | 2040 | 2568 | 52.2% |
| c | 1160 | 1548 | 1688 | 1855 | 30.8% |
| d | 1406 | 1682 | 1982 | 2336 | 39.8% |
| e | 3925 | 5346 | 6754 | 7124 | 49.7% |
| f | 561 | 845 | 1130 | 1257 | 69.8% |
| g | 969 | 1126 | 1312 | 1323 | 25.8% |
| h | 685 | 850 | 900 | 1077 | 42.0% |
| i | 4916 | 4242 | 7017 | 6731 | 50.1% |

The preferred embodiments of the present invention are disclosed as the description above and drawings. All features disclosed by the present application may be combined with other means, and each feature disclosed in the present application may be replaced by the same, equivalent or similar target features. Thus, apart from particularly obvious features, all the features disclosed in the present application are merely examples of equivalent or similar features. With the description of the preferred embodiments of the present invention, a person skilled in the art would be able to understand that the present invention is a novel, inventive and industrially applicable invention, and possess development values. Moreover, various modifications (for example, adjusting relative positions of some components or the structure of a diversion device) may be made to the present invention by a person skilled the art, and are encompassed within the scope of the appended claims.

What is claimed is:

1. An in-cavity cleaning method, comprising:
a lower electrode temperature control step of controlling a lower electrode to a predetermined temperature;
an electrode distance adjustment step of elevating the lower electrode and controlling a distance between an upper electrode and the lower electrode;
a film deposition step of depositing a film on a substrate;
a cleaning gas introducing step of introducing a cleaning gas in a plasma state from the upper electrode of a cavity into the cavity; and
a cleaning gas pressure control step of adjusting a pressure of the cleaning gas to repeatedly switch between a first pressure and a second pressure for a plurality of number of times by a valve adjustment means,
wherein the first pressure is greater than the second pressure.

2. The cleaning method of claim 1, wherein the predetermined temperature is 150° C. to 400° C.

3. The cleaning method of claim 1, further comprising:
driving the elevation of the lower electrode by a motor, and controlling the distance between the upper electrode and the lower electrode to be 6 to 15 mm.

4. The cleaning method of claim 1, wherein the cleaning gas is NF₃, and after fluorine ions are formed therefrom by a plasma source generator, the fluorine ions are introduced into the cavity via the upper electrode.

5. The cleaning method of claim 1, wherein the cleaning gas enters the cavity by a flow rate of 1500 to 4500 sccm.

6. The cleaning method of claim 1, wherein the valve adjustment means controls the pressure of the cleaning gas in the cavity by a butterfly valve.

7. The cleaning method of claim 1, wherein the pressure in the cavity switches between the first pressure and the second pressure in a cleaning process, wherein the first pressure is 3 to 6 torr and the second pressure is 0.5 to 2 torr.

8. The cleaning method of claim 1, wherein the first pressure is a high-pressure state and the second pressure is a low-pressure state, and a switching frequency between the two is once per 5 to 15 seconds.
